(19) United States
(12) Patent Application Publication
(10) Pub. No.: US 2020/0026391 A1
(43) Pub. Date: Jan. 23, 2020

(54) TOUCHSCREEN PANEL AND DISPLAY DEVICE INCLUDING THE SAME

(71) Applicant: Sharp Kabushiki Kaisha, Osaka (JP)

(72) Inventor: Shinji TOMOKAWA, Sakai City (JP)

(21) Appl. No.: 16/502,066

(22) Filed: Jul. 3, 2019

Related U.S. Application Data
(60) Provisional application No. 62/700,963, filed on Jul. 20, 2018.

(51) Int. Cl. G06F 3/044; H05K 1/11; H05K 1/18

(52) U.S. Cl. CPC G06F 3/0445; G06F 3/0446; H05K 1/118; H05K 2201/056; G06F 2203/04102; H05K 2201/10136; H05K 2201/10128; H05K 1/189

(57) ABSTRACT

A touchscreen panel includes a touch panel having a plate shape having a front surface and a back surface, and a flexible circuit board one end of which is electrically connected to the touch panel. The touch panel includes a detection region where contact of an operator from a front surface side can be detected, and a terminal region where connection terminals to be connected to the flexible circuit board are disposed on aback surface side. The detection region and the connection terminals are connected to each other via panel lines formed on the touch panel, and one of the panel lines is a detour line that is connected to one of the connection terminals from a side where the detection region is not present seen from the connection terminals.

### CROSS REFERENCE TO RELATED APPLICATION

This application claims priority from U.S. Provisional Application No. 62/700,963 filed on Jul. 20, 2018. The entire contents of the priority application are incorporated herein by reference.

### TECHNICAL FIELD

The present technology described herein relates to a touchscreen panel and a display device including a touch panel.

### BACKGROUND

A conventional touchscreen panel is configured by electrically connecting a touch panel to signal lines through which detection signals indicating that an operator touches the touchscreen panel are output. A flexible circuit board is usually used as the signal lines. Connection terminals formed on the touch panel are electrically connected to input/output terminals formed on the flexible circuit board through a connection pad. A display device including a display panel such as a liquid crystal display panel on a back surface side of the touch panel a part of which is transparent has been generally known. One example of such a display device is disclosed in Japanese Unexamined Patent Application Publication No. 2013-33549.

Japanese Unexamined Patent Application Publication No. 2013-33549 discloses a display device including X electrodes formed on a front surface of an electrostatic capacitive touch panel, Y electrodes intersecting with the X electrodes, a back electrode formed on a back surface of the electrostatic capacitive touch panel, X electrode signal wiring for supplying signals from both ends of the X electrodes, Y electrode signal wiring for supplying signals from both ends of the Y electrodes, connection part formed on the front surface of the electrostatic capacitive touch panel and including connection terminals connected to the X electrode signal wiring and the Y electrode signal wiring, and a flexible circuit board connected to the X electrode signal wiring and the Y electrode signal wiring at the connection part. Back connection pads are formed adjacently to the connection part on the front surface of the electrostatic capacitive touch panel, in alignment with the connection terminals, and outside the connection terminals connected to the Y electrode signal wiring. The connection terminals and the back connection pads are connected with each other through wiring formed on the front surface of the electrostatic capacitive touch panel. The back connection pads and the back electrode are connected with each other through conductive members. Voltage is supplied from the flexible circuit board to the back electrode.

A display device may be configured to have a connection method of connecting the connection terminal and the flexible circuit board as described in FIG. 10. FIG. 10 is an enlarged side cross-sectional view of a part of a display device 000. As illustrated in FIG. 10, a display device 000 includes a display panel 010 (including a backlight), a touchscreen panel 020, and a protection plate 030. The display panel 010 is arranged on a back surface side of the touchscreen panel 020 and the protection plate 030 is arranged on a front surface side of the touchscreen panel 020. The touchscreen panel 020 includes a touch panel 021 and a flexible circuit board 022.

FIG. 11 illustrates aback side view of the touch panel 021 of the display device 000 according to a related art. Most area of the touch panel 021 except for a frame area thereof is a detection region 0211 that can detect an operator's contact from the front surface side. X electrodes 0218 and Y electrodes 0219 are formed in the detection region 0211.

The frame area includes a terminal region 0212 in a part thereof. Connection terminals 0213 are arranged in the terminal region 0212 on aback surface of the touch panel 021 while being uncovered. Each of the electrodes in the detection region 0211 is connected to a corresponding connection terminal 0213 through a panel line 0214. A routing area used for routing the panel lines 0214 is necessary between the detection region 0211 and the terminal region 0212 because of a structure thereof. A required width of the routing area is proportional to the number of the panel lines 0214 extending in the routing area. On the touch panel 021, the lines are not necessary to extend between a connection terminal 0213 side edge 0215 of a touch panel and the connection terminals 0213. Therefore, to reduce the frame area including the terminal region 0212, the connection terminals 0213 are arranged adjacent to the edge 0215 and at an edge of the touch panel 021.

Since the connection terminals 0213 are arranged at the edge of the touch panel 021, as illustrated in FIG. 10, the flexible circuit board 022 that is connected to the connection terminals 0213 is connected to the edge of the touch panel 021.

The flexible circuit board 022 is flexible; however, the flexible circuit board 022 may be broken or lines may be disconnected if it is bent at a small curvature. Therefore, it is preferable to be bent at a curvature as great as possible, and it may be bent in a cylindrical shape. The flexible circuit board 022 is curved in a cylindrical shape to extend toward the back surface of the display panel 010 and a part of the flexible circuit board 022 is on the back surface side of the display panel 010. However, if the flexible circuit board 022 that is connected to the edge of the touch panel 021 is curved in a cylindrical shape, the cylindrical section of the flexible circuit board 022 projects outward from the touch panel 021 and the protection plate 030 and seen in a front view. Therefore, the frame area of the display device 000 becomes necessarily greater because of the projected cylindrical section of the flexible circuit board 022.

### SUMMARY

The present technology described herein was made in view of the above circumstances and an object is to reduce a frame area of a display device.

According to the technology described herein, a touchscreen panel includes a touch panel having a plate shape having a front surface and a back surface, and a flexible circuit board one end of which is electrically connected to the touch panel. The touch panel includes a detection region where contact of an operator from a front surface side can be detected, and a terminal region where connection terminals to be connected to the flexible circuit board are disposed on a back surface side. The detection region and the connection terminals are connected to each other via panel lines formed on the touch panel, and one of the panel lines is a detour line that is connected to one of the connection terminals from a side where the detection region is not present seen from the connection terminals. According to the touchscreen panel having such a configuration, the number of the panel lines that necessarily extend in an area between the detection region and the connection terminals is decreased and an area between the detection region and the connection terminals can be reduced. On the other hand, the panel line is formed as a detour line in a region on a side where the detection region is not present seen from the connection terminals. Therefore, the flexible circuit board to be connected to the connection terminals is deformed toward the side where the detection region is not present and stored while overlapping the region where the detour line is formed. Accordingly, an area of the flexible circuit board that projects from the touch panel is decreased. Therefore, if the touchscreen panel is used as a component of a display device, the display device with a small frame area is produced.

According to the technology described herein, a display device includes the touchscreen panel. The detection region includes a transparent part, a display panel is disposed on a back surface side of the detection region, and a display region of the display panel is superimposed on a back surface of the detection region.

According to the touchscreen panel and the display device of the present technology, the frame area of the display device can be reduced.

### BRIEF DESCRIPTION OF THE DRAWINGS

FIG. 1 is a perspective view illustrating a display device according to a first embodiment.

FIG. 2 is an exploded perspective view illustrating the display device according to the first embodiment.

FIG. 3 is a back side view of a touch panel included in the display device according to the first embodiment.

FIG. 4 is a back side view of a first electrode layer included in the display device according to the first embodiment.

FIG. 5 is a back side view of a second electrode layer included in the display device according to the first embodiment.

FIG. 6 is a perspective view of the display device that is assembled (before completion) according to the first embodiment.

FIG. 7 is an enlarged cross-sectional view illustrating a part of the display device according to the first embodiment.

FIG. 8 is an exploded perspective view illustrating a display device according to a second embodiment.

FIG. 9 is a back side view of a touch panel included in the display device according to the second embodiment.

FIG. 10 is an enlarged cross-sectional view illustrating a part of a display device according to a related art.

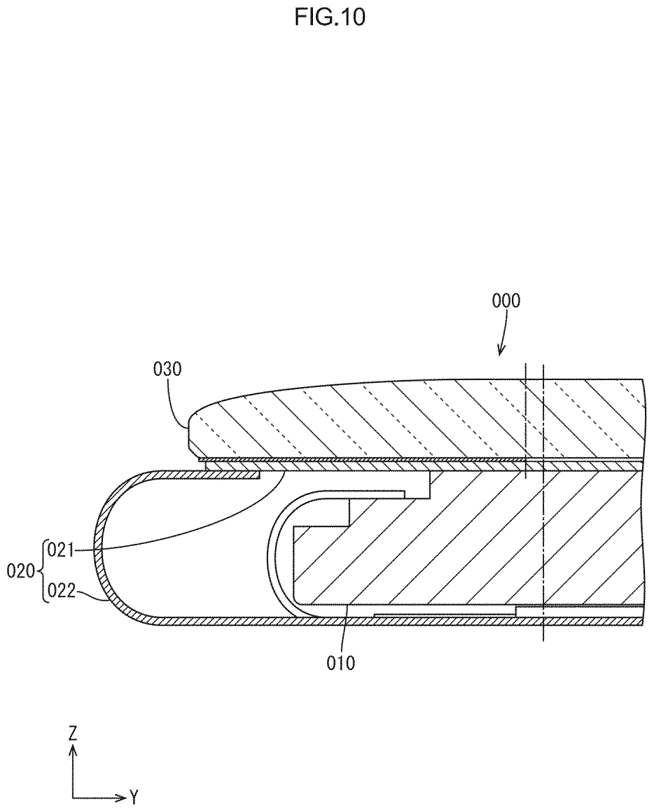

FIG. 11 is a back side view of a touch panel included in the display device according to a related art.

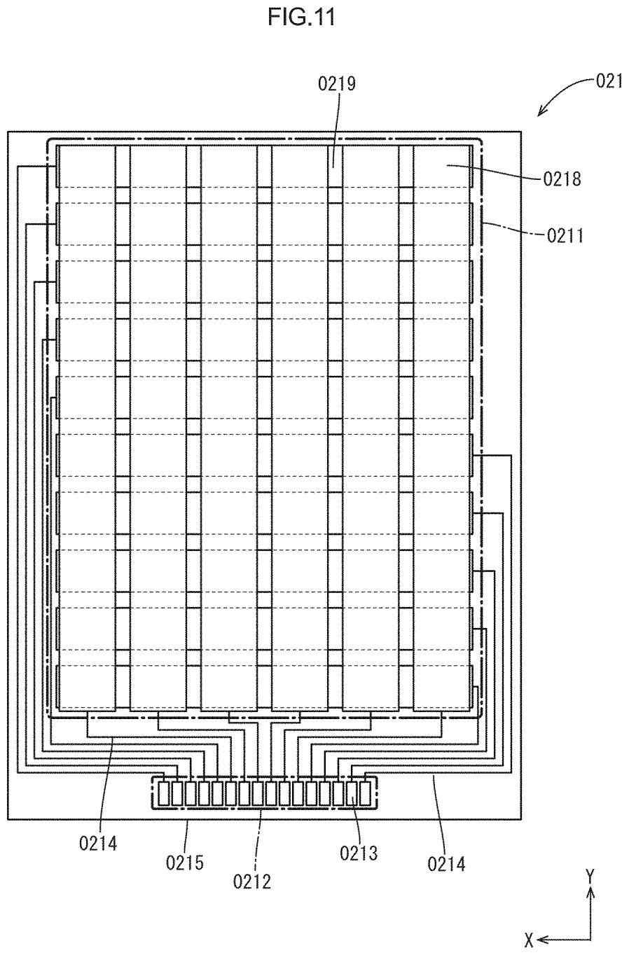

### DETAILED DESCRIPTION

### First Embodiment

<Liquid Crystal Display Device 100>

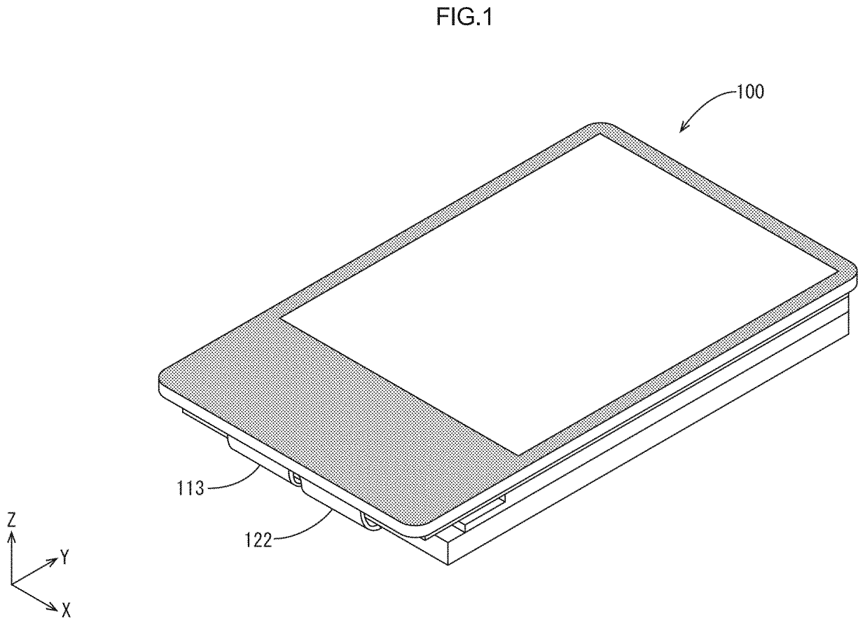

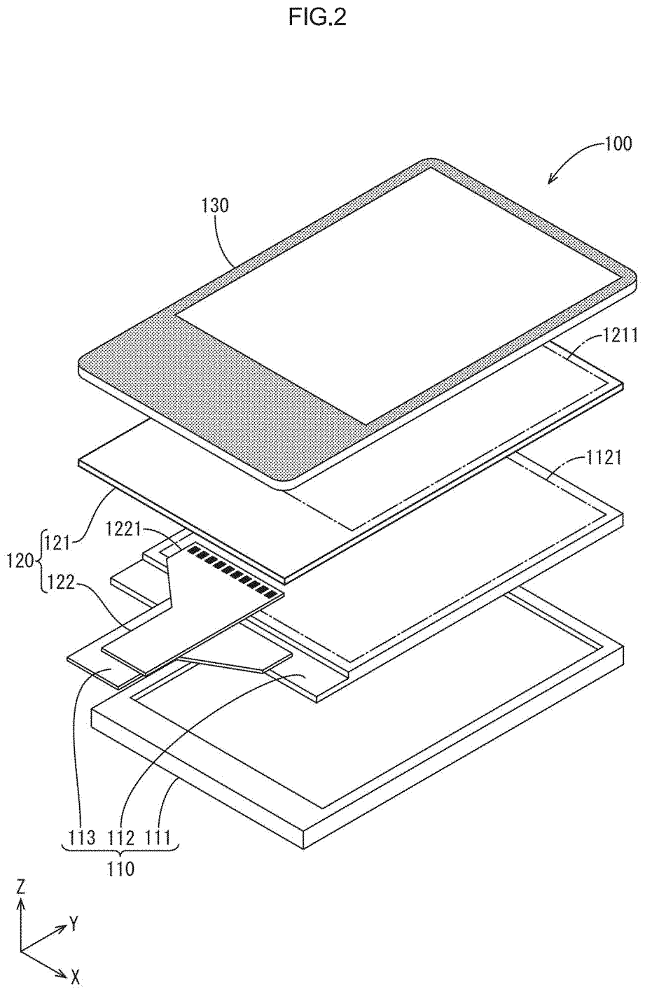

FIG. 1 is a perspective view illustrating a display device 100 according to a first embodiment. FIG. 2 is an exploded view of the display device 100. A configuration of the display device 100 will be described with reference to FIGS. 1 and 2. In this specification, surfaces facing a direction same as a display surface displaying an image faces are referred to as front surfaces and surfaces facing an opposite side therefrom are referred to as back surfaces. Namely, in FIGS. 1 and 2, a surface facing an upper side is referred to as a front surface and a surface facing a lower side is referred to as a back surface. With reference to axes illustrated in FIG. 1, a direction forwarding from the back surface to the front surface is a Z direction. Surfaces facing directions perpendicular to the Z direction are referred to as side surfaces. Namely, surfaces facing ±X direction and ±Y direction that are perpendicular to the Z direction are the side surfaces. The display device 100 has a substantially quadrangular shape and a direction in which long sides thereof extend is the Y direction and a direction in which short sides thereof extend is the X direction.

The display device 100 includes a display panel 110, a touchscreen panel 120, and a protection plate (a cover glass) 130.

<Display Panel 110>

The display panel 110 has a plate shape and has a display region 1121 on the front surface thereof. The display panel 110 displays a certain image in the display region 1121 by input of electrical signals. The display panel 110 includes a backlight 111, a liquid crystal panel 112, and a flexible circuit board 113.

<Liquid Crystal Panel 112>

The liquid crystal panel 112 includes two quadrangular transparent substrates and a liquid crystal layer that is between the two transparent substrates. The liquid crystal layer includes liquid crystals that are sealed with sealing material. The liquid crystal panel 112 has a plate shape. Material of the two transparent substrates is glass but may be other material such as plastic. Electrodes are arranged on at least a part of a liquid crystal layer side section of the two transparent substrates and a potential difference therebetween can be controlled. The liquid crystals in the display region 1121 are aligned in a specific direction by the application of the potential difference between the electrodes. An alignment film may be provided on the liquid crystal layer side of the transparent substrate such that the liquid crystals are aligned in a certain direction when no potential difference is created between the electrodes. A spacer may be provided to keep a constant distance between the two transparent substrates. The electrodes may be formed in any shape. For example, the electrodes may have an electrode pattern arrayed in a regular form or an electrode pattern of a graphic pattern, a character, or a picture. The alignment direction of the liquid crystals may be various directions such as a vertical alignment or a horizontal alignment. A transistor component may be included to control the potential difference between the electrodes.

Out of the two transparent substrates, the front surface side transparent substrate has a long-side dimension that is smaller than a long-side dimension of the back surface side transparent substrate. A front surface of one of the short-side sections of the back surface side transparent substrate is exposed outside. The liquid crystal layer is not disposed on the exposed section and one edge section of the flexible circuit board 113 is connected thereto. Electric signals for controlling the alignment of the liquid crystals included in the liquid crystal panel 112 are transferred to the liquid crystal panel 112 through the flexible circuit board 113. The flexible circuit board 113 including a flexible board and conductors printed thereon. The liquid crystal panel 112 controls the potential difference between the electrodes based on the electric signals supplied to the conductors of the flexible circuit board 113.

The liquid crystal panel 112 includes polarizing plates on the front surface and the back surface thereof to cover the display region 1121. The polarizing plate has a function of polarizing light passing through a thickness thereof.

<Backlight 111>

The backlight 111 has a quadrangular plate shape having a substantially same shape as that of the liquid crystal panel 112 seen from the front surface side. The backlight 111 includes a light exit region through which the light exits. The backlight 111 is disposed with overlapping a back surface of the liquid crystal panel 112. The backlight 111 includes a light emitting diode that converts electric energy into light and a light guide plate that transmits, reflects and refracts the light from the light emitting diode into planar flux of light. Other light sources such as a CCFL tube and an organic EL may be used instead of the light emitting diode. A diffuser sheet, a prism sheet, a lens sheet, or a reflection sheet may be used to change an exit direction of light. The light guide plate may not be included.

<Touchscreen Panel 120>

The touchscreen panel 120 includes a touch panel 121 and a flexible circuit board 122. The touchscreen panel 120 is an electrostatic capacitance type.

<Touch Panel 121>

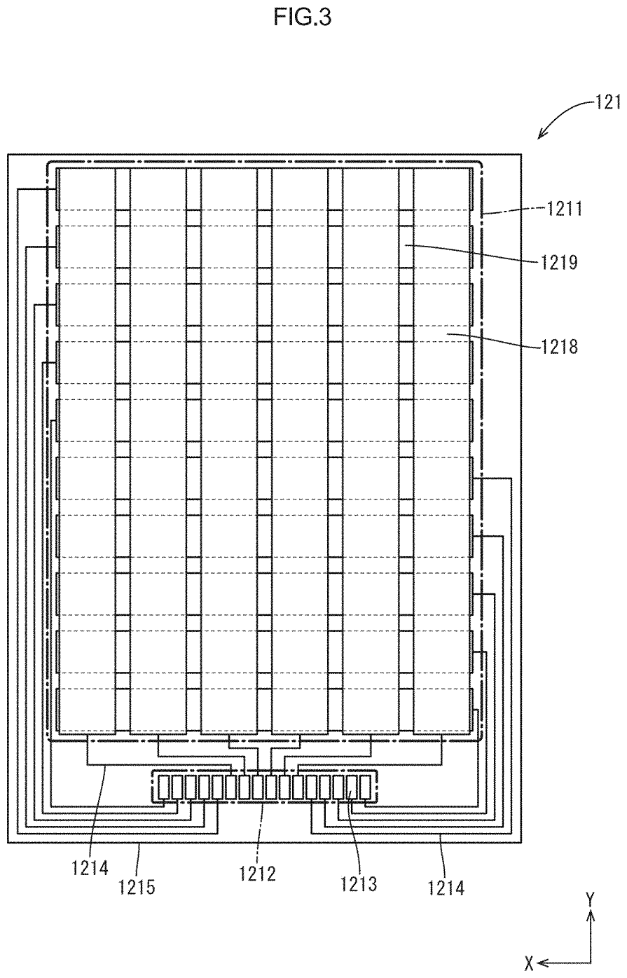

With reference to FIGS. 3 to 5, a configuration of the touch panel 121 will be described. FIG. 3 is a back side view of the touch panel 121. The touch panel 121 has a substantially quadrangular shape.

Most area of the touch panel 121 except for the frame area thereof is a detection region 1211 where an operator's contact from the front surface side can be detected. The detection region is transparent and most of visible light rays that enter through the back surface transmit through the detection region toward the front surface side.

A terminal region 1212 is included in a part of the frame area that is included in an outer peripheral section around the detection region 1211 (one edge side of the quadrangular detection region 1211, here, specifically, the frame area in one section of a short side). The terminal region 1212 is a thin elongated area extending in the X direction and the frame area having the terminal region 1212 is wider than other frame area. In the terminal region 1212, connection terminals 1213 are arranged on a back surface of the touch panel 121 while being uncovered. Three or more connection terminals 1213 are arranged linearly parallel to a linear edge 1215 of the touch panel 121. The detection region 1211 is on a +Y direction side seen from the terminal region 1212 and the linear edge 1215 that is closest to the terminal region 1212 extends in the X direction. The connection terminals 1213 are arranged in the X direction. Namely, the X direction in which the three or more connection terminals 1213 are arranged linearly is perpendicular to the +Y direction where the detection region 1211 is disposed seen from the connection terminals 1213 (a direction in which the connection terminals 1213 and the detection region 1211 are arranged, specifically, a direction perpendicular to the short side of the detection region 1211). The direction in which the three or more connection terminals 1213 are linearly arranged is parallel to a direction in which the linear edge 1215 extends. The electrodes in the detection region 1211 are connected to respective corresponding connection terminals 1213 through panel lines 1214.

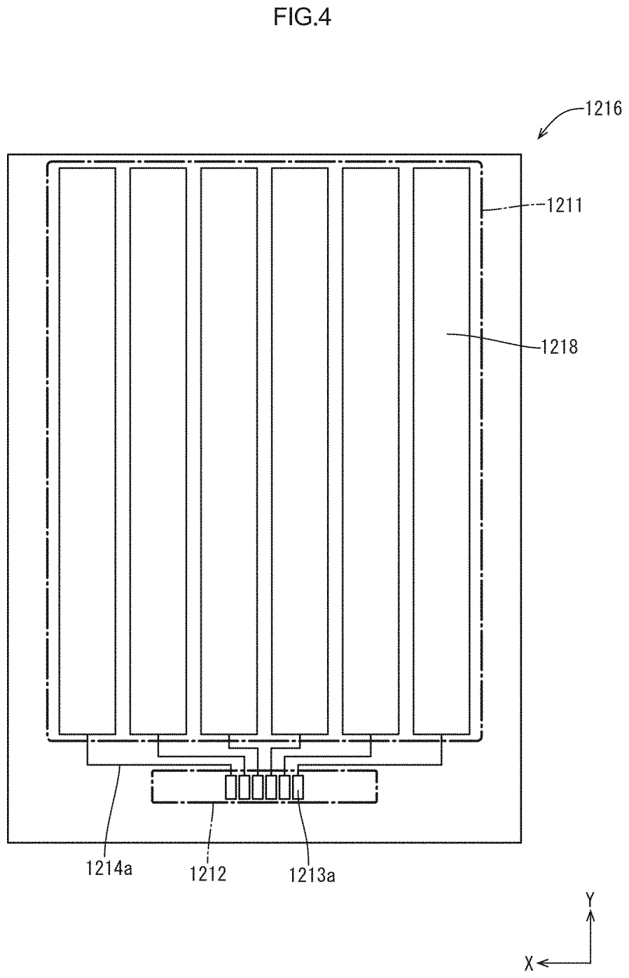

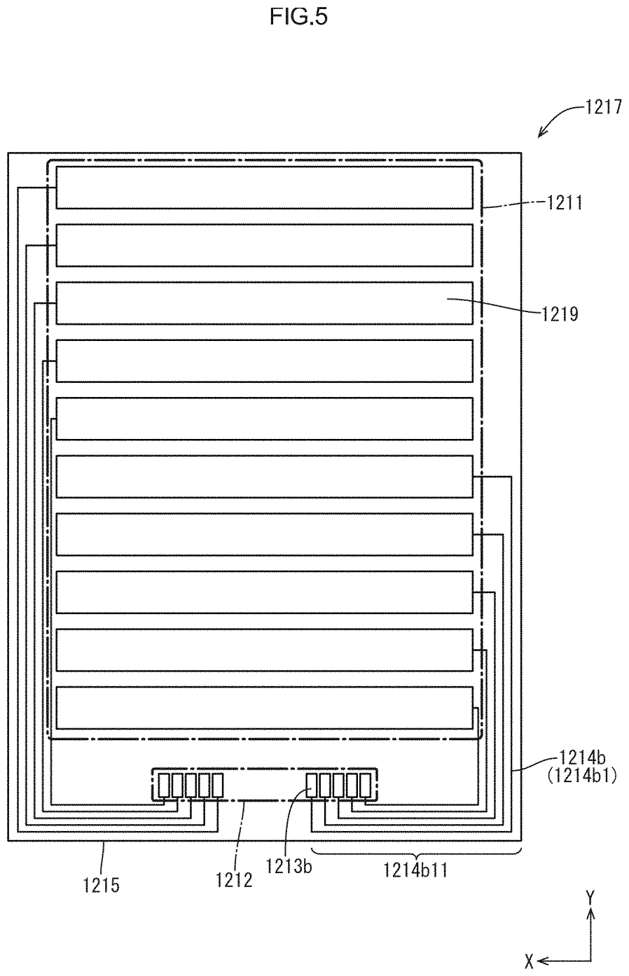

The touch panel 121 includes a first electrode layer 1216 and a second electrode layer 1217 that are stacked (superimposed) on each other. A back side view of the first electrode layer 1216 is illustrated in FIG. 4 and a back side view of the second electrode layer 1217 is illustrated in FIG. 5.

<First Electrode Layer 1216>

X electrodes 1218 that are elongated in the Y direction are arranged in the X direction in the detection region 1211 of the first electrode layer 1216. The X electrodes 1218 are transparent with respect to visible light and preferably formed from a transparent conductive film such as indium tin oxide (ITO). The detection region 1211 of the first electrode layer 1216 is transparent since the transparent X electrodes 1218 are arranged on a transparent substrate. Each of the X electrodes 1218 is electrically connected to the connection terminal 1213a corresponding to each X electrode 1218 through a panel line 1214a. The connection terminals 1213a that are connected to the X electrodes 1218 are arranged in the X direction in a middle area of the terminal region 1212.

<Second Electrode Layer 1217>

Y electrodes 1219 that are elongated in the X direction are arranged in the Y direction in the detection region 1211 of the second electrode layer 1217. The Y electrodes 1219 are transparent with respect to visible light and preferably formed from a transparent conductive film such as indium tin oxide (ITO). The detection region 1211 of the second electrode layer 1217 is transparent since the transparent Y electrodes 1219 are arranged on a transparent substrate. Each of the Y electrodes 1219 is electrically connected to the connection terminal 1213b corresponding to each Y electrode 1219 through a panel line 1214b. The connection terminals 1213b that are connected to the Y electrodes 1219 are arranged in the X direction and arranged in two end sections of the terminal region 1212 with respect to the X direction. One of the panel lines 1214b (all of the panel lines 1214b in this embodiment; however, at least one of the panel lines 1214b) is a detour line 1214b1. The detour line 1214b1 is connected to the connection terminal 1213b from a side where the detection region 1211 is not present seen from the connection terminal 1213b, that is, a −Y direction side or an edge 1215 side.

The detour line 1214b1 has a detour section 1214b11 that extends on an outer side of the connection terminal 1213b. The detour section 1214b11 extends along an outer peripheral edge 1215 that is on a side where the detection region 1211 is not present seen from the connection terminal 1213b. The connection terminals 1213b are arranged on an inner side with respect to the detour section 1214b11 within a plane surface area of the touch panel 121, that is, far away from the outer periphery including the edge 1215.

The touch panel 121 includes the first electrode layer 1216 and the second electrode layer 1217 that are stacked on each other. An insulation layer is between the X electrodes 1218 and the Y electrodes 1219 so that the X electrodes 1218 and the Y electrodes 1219 are not electrically connected. The connection terminals 1213a and the connection terminals 1213b are arranged next to each other seen from the back side of the touch panel 121 and form the connection terminal 1213 as a whole. The connection terminal 1213 is through a layer on which the panel lines 1214 are formed and a layer on the most outer back side layer (for example, a protection layer) and is exposed from the back surface of the touch panel 121. The panel lines 1214 (1214a, 1214b) may be formed on any one of the layers.

The shape of the X electrodes 1218 and the Y electrodes 1219 is not necessarily an elongated quadrangular shape but may be other shapes. The X electrodes 1218 and the Y electrodes 1219 may be disposed on the same layer. At sections where the X electrodes 1218 and the Y electrodes 1219 intersect, conductive members that allow the X electrodes 1218 and the Y electrodes 1219 to intersect at different levels may be included in a different layer.

<Flexible Circuit Board 122>

The flexible circuit board 122 is obtained by printing a conductive foil such as copper on thin insulating material such as plastic and has flexibility. The conductive foil is covered with an insulating member such as a solder resist to be protected and the flexible circuit board 122 has FPC terminals 1221 on a surface of one edge thereof. The FPC terminals 1221 are an exposed conductive foil. The flexible circuit board 122 and the touch panel 121 are designed as follows. If a front surface of the flexible circuit board 122 and a back surface of the touch panel 121 are opposite each other to be positioned, the FPC terminals 1221 are superimposed on the connection terminals 1213, respectively. The FPC terminals 1221 and the connection terminals 1213 are electrically connected to each other, respectively, with press fitting, solder fusing, an anisotropic conductive film (ACF), or direct bonding.

<Protection Plate (Cover Glass) 130>

The protection plate 130 is attached to a front surface of the touch panel 121. The protection plate 130 is made of glass and/or resin. The protection plate 130 is preferably transparent in a region that overlaps the display region 1121 of the display panel 110 (overlapping in the Z direction). Other sections of the protection plate 130 may be colored. The protection plate 130 protects the touchscreen panel 120 and the display device 100 from friction, shock, dust, and chemical pollution and also provides aesthetic design. The protection plate 130 is not a component that is necessary for a main function such as displaying images or detection of touch and therefore is not necessarily included.

<Assembling of Display Device 100>

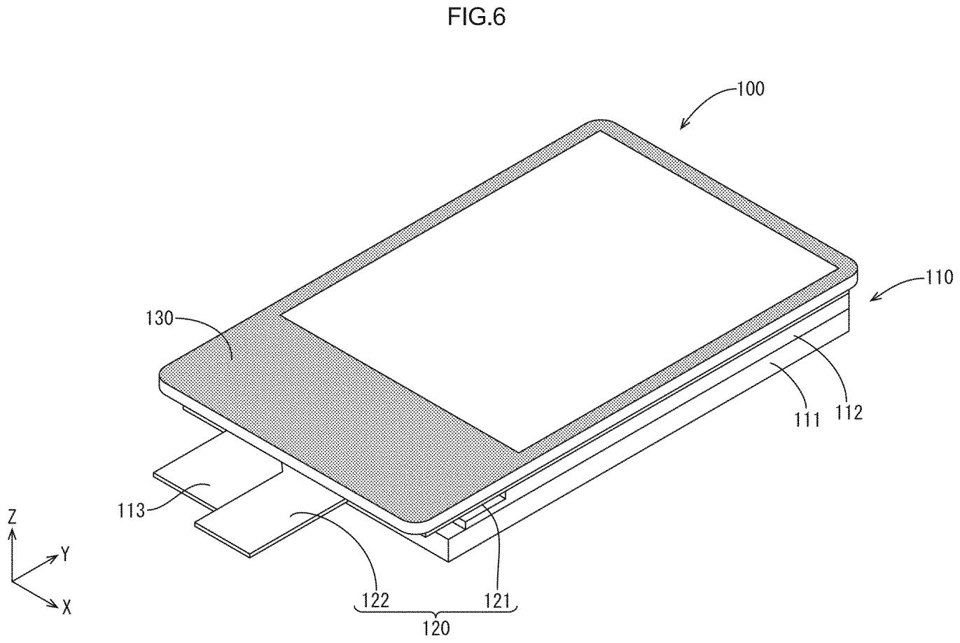

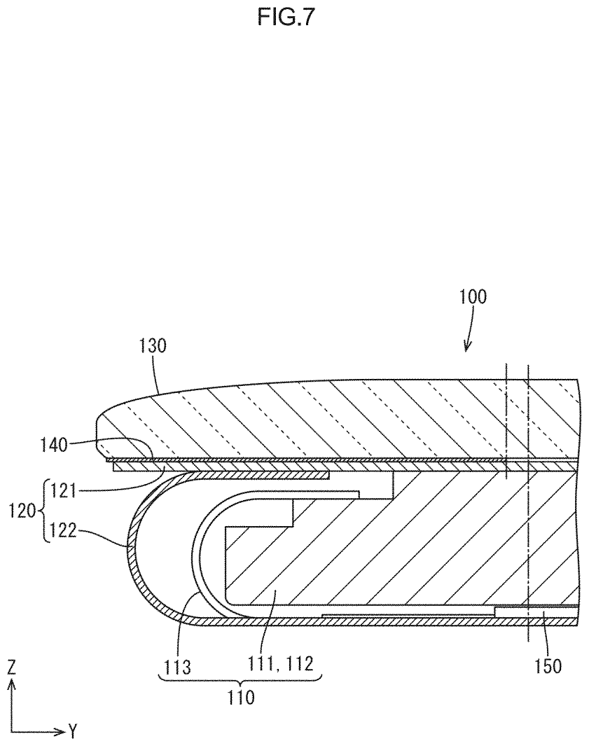

Assembling of the display device 100 will be described with reference to FIGS. 6 and 7. FIG. 6 is a perspective view illustrating the display device 100 including the backlight 111, the liquid crystal panel 112, and the flexible circuit board 113, the touchscreen panel 120 including the touch panel 121 and the flexible circuit board 122, and the protection plate 130 that are illustrated in FIG. 2 and put together. The display device 100 is provided by connecting one end of the flexible circuit board 113 to the liquid crystal panel 112 and arranging the backlight 111 on the back surface side of the liquid crystal panel 112. The touchscreen panel 120 is provided by electrically connecting one end of the flexible circuit board 122 to the touch panel 121. Next, the liquid crystal panel 112 is disposed on the back surface side of the detection region 1211 of the touch panel 121 such that the display region 1121 of the liquid crystal panel 112 is superimposed on the back surface of the detection region 1211.

A method of assembling the display device 100 and fixing components may be selected as appropriate. For example, optical clear adhesive (OCA) is appropriately used for fixing the protection plate 130 and the touch panel 121 and fixing the touch panel 121 and the liquid crystal panel 112 since uniform transparency is required. It is appropriate to fix the frame area with a double-sided adhesive tape for fixing the liquid crystal panel 112 and the backlight 111 since an air layer is preferably provided therebetween. Methods of fixing with fixing members such as a chassis, a mold, a housing, a bezel, and a casing may be used. An appropriate fixing method may be selected as appropriate according to various conditions for different products such as material or size of each component, required strength, and an area that can be used as an adhesive surface.

As illustrated in FIG. 6, when the components are put together (another end of the flexible circuit board is not fixed, the display device 100 before completion), another ends of the flexible circuit boards 113, 122 project from the protection plate 130 or the touch panel 121 and seen from the front side of the display device 100. FIG. 7 is an enlarged cross-sectional view of the display device 100 along a Y-Z plane surface. As illustrated in FIG. 7, the flexible circuit boards 113, 122 are bent in a cylindrical form such that the other ends thereof are disposed on the back surface of the display panel 110 and fixed thereto. An appropriate fixing method such as an adhesive tape or screw fixing may be selected as appropriate as the fixing method.

A bending direction of the flexible circuit board 113 and the flexible circuit board 122 is vertical to the X direction that is an arrangement direction in which the connection terminals 1213 are arranged linearly. Therefore, if seen from the cross-sectional surface along the Y-Z surface that is vertical to the X direction, the flexible circuit boards 113, 122 are seen from the side surface thereof. Therefore plate surfaces are less likely to be seen.

As illustrated in FIG. 7, the touch panel 121 and the protection plate 130 projects further in the −Y direction compared to the −Y direction side edge of the display panel 110. Therefore, the −Y direction side edge section of the display panel 110 is not projected and seen in the front view of the display device 100. Similarly, the flexible circuit board 122 and the flexible circuit board 113 are disposed on the back surface side (the −Z direction side) of the −Y direction side projected section of the touch panel 121 or the protection plate 130 and are arranged behind the touch panel 121 or the protection plate 130. The touch panel 121 and the protection plate 130 are fixed with an adhesive layer (OCA) 140.

The flexible circuit board 122 may be connected to one of a transistor element, a resistance element, and a condenser element, a chip 150 enclosing the one element with resin, or a circuit board having the chip 150 thereon. Such an element may be disposed on the back surface of the display panel 110 with the flexible circuit board 122. Such an element is apart of a circuit for applying a voltage to the X electrode 1218 or the Y electrode 1219 of the touch panel 121, detecting an electrostatic capacitance between the X electrode 1218 and the Y electrode 1219, and specifying a position where an operator touches in the detection region 1211. However, such an element may be a circuit for performing another process.

The flexible circuit board 122 may be integrally formed with the flexible circuit board 113. In such a configuration, one end of the flexible circuit board may be branched into two parts including a part connected to the display panel 110 and a part connected to the touch panel 121. The flexible circuit board 122 and the flexible circuit board 113 may be connected to each other.

### Advantageous Effects of the Present Embodiment

The touchscreen panel 120 of the present embodiment includes a touch panel 121 that is a plate member having a front surface and a back surface, and the flexible circuit board 122 one end thereof being electrically connected to the touch panel 121. The touch panel 121 includes the detection region 1211 where contact of an operator from the front surface side is detected and the terminal region 1212 where the connection terminals 1213 to be connected to the flexible circuit board 122 are disposed on the back surface side. The detection region 1211 and the connection terminals 1213 are connected with the panel lines 1214 that are formed on the touch panel 121 and at least one of the panel lines 1214 is a detour line 1214b1 that is connected to the connection terminal 1213b from a side without having the detection region 1211 seen from the connection terminal 1213b.

Accordingly, the detour line 1214b1 is connected to the connection terminal with the detour section 1214b11 that extends along the outer periphery of the touch panel 121 on the side where the detection region 1211 is not present seen from the connection terminal 1213b. According to such a configuration, the number of panel lines 1214 that necessarily extend in the area between the detection region 1211 and the terminal region 1212 is decreased and an area between the detection region 1211 and the terminal region 1212 (an area between the detection region 1211 and the connection terminal 1213) can be reduced. The connection terminal 1213b connected to the detour line 1214b1 is arranged on an inner side with respect to the detour section 1214b11 within a plane surface of the touch panel 121. According to such a configuration, the connection terminal 1213b can be arranged within a surface area of the touch panel 121 without increasing a width of the frame area including the terminal region 1212.

The display device 100 of the present embodiment includes the touchscreen panel 120 of the present embodiment. At least a part of the detection region 1211 is transparent and the display panel 110 is arranged on the back surface side of the detection region 1211 such that the display region 1121 of the display panel 110 overlaps the back surface of the detection region 1211. Accordingly, an operator can touch the overlapping detection region while seeing an image displayed on the display region 1121. The frame area of the display device 100 can be reduced.

Further, the flexible circuit board 122 is bent toward the back surface side of the display panel 110 and a part of the flexible circuit board 122 is disposed on the back surface side of the display panel 110. Accordingly, the frame area of the display device 100 can be reduced.

In the touchscreen panel 120 of the present embodiment, the connection terminal 1213b is arranged on an inner side within a plane surface of the touch panel 121. Therefore, according to the display device 100 of the present embodiment, the flexible circuit board 122 to be connected to the connection terminal 1213b can be bent at a position that is on an inner side from the edge 1215 of the touch panel 121. Therefore, an area of a part of the flexible circuit board 122 that projects from the back surface of the touch panel 121 and seen from a front view can be reduced. Furthermore, the flexible circuit board 122 can be hidden on the back surface side of the touch panel 121 from a front view. Accordingly, the frame area of the display device 100 can be further reduced.

The touchscreen panel 120 of the present embodiment can be used as a component included in the display device 100 of the present embodiment. Therefore, the display device 100 having a small frame area can be produced.

According to the touchscreen panel 120 of the present embodiment, three or more connection terminals 1213 are arranged linearly. According to such a configuration, the width of the terminal region 1212 in the direction (the Y direction) perpendicular to the arrangement direction of the connection terminals 1213 (the X direction) is reduced and the frame area of the touch panel 121 can be reduced.

Further, according to the touchscreen panel 120 of the present embodiment, the direction in which the three or more connection terminals 1213 are arranged linearly is perpendicular to the direction in which the detection region 1211 extends seen from the connection terminals 1213 (+Y direction). Therefore, the connection terminals 1213 are arranged along the outer periphery of the detection region 1211. Thus, the frame area of the touch panel 121 can be reduced.

The touchscreen panel 120 of the present embodiment includes the linear edge 1215 that is closest to the connection terminals 1213 in a plan view, and the direction in which three or more connection terminals 1213 arranged linearly (the X direction) is parallel to the direction in which the edge 1215 extends (the X direction). Therefore, the connection terminals 1213 are arranged along the outer periphery of the touch panel 121. Accordingly, the frame area of the touch panel 121 can be reduced.

According to the touchscreen panel 120 of the present embodiment, the touchscreen panel 120 is an electrostatic capacitance type. Therefore, unlike the matrix switching type, the touching can be detected unless an operator presses down the touch panel. Touching can also be detected just before the touching. The electrostatic capacitance type touchscreen has advantages as follows. Unlike the resistive film type, the detection accuracy is not lowered by increasing the number of the X electrodes and the Y electrodes even if the area of the detection region is increased. Unlike the infrared type touchscreen, the touchscreen is not adversely affected by external light. Unlike the electromagnetic induction type, an exclusive touch pen is not necessary. The touchscreen panel 120 may be a touchscreen panel of other type than the electrostatic capacitance type.

According to the touchscreen panel 120 of the present embodiment, the flexible circuit board is connected to one of a transistor element, a resistance element, and a condenser element, the chip 150 enclosing the one element with resin, or a circuit board having the chip 150 thereon. Therefore, voltage is applied to the X electrode 1218 or the Y electrode 1219 of the touch panel 121, an electrostatic capacitance between the X electrode 1218 and the Y electrode 1219 is detected, a position where an operator touches in the detection region 1211 is specified, or other process can be performed.

The touchscreen panel 120 of the present embodiment includes the protection plate 130 on a front surface of the touch panel 121. Therefore, the protection plate 130 protects the touchscreen panel 120 from friction, shock, dust, and chemical pollution from the front surface side and also provides aesthetic design.

According to the display device 100 of the present embodiment, the flexible circuit board 122 is bent in a direction (the Y direction and the Z direction) that is perpendicular to the direction in which the three or more connection terminals 1213 are linearly arranged (the X direction). Therefore, the flexible circuit board 122 can be bent at a section adjacent to the connection terminals 1213. This further reduces the frame area of the display device 100.

According to the display device 100 of the present embodiment, the bent flexible circuit board 122 is hidden on the back surface side of the touch panel 121 seen from the front surface side of the touch panel 121. This further reduces the frame area of the display device 100.

According to the display device 100 of the present embodiment, the flexible circuit board 122 is connected to one of a transistor element, a resistance element, and a condenser element, the chip 150 enclosing the one element with resin, or a circuit board having the chip 150 thereon. The element is arranged on a back surface side of the display panel 110. Therefore, voltage is applied to the X electrode 1218 or the Y electrode 1219 of the touch panel 121, an electrostatic capacitance between the X electrode 1218 and the Y electrode 1219 is detected, a position where an operator touches in the detection is specified, or other process can be performed, and also the frame area of the display device 100 is reduced.

The display device 100 of the present embodiment includes the protection plate 130 on a front surface of the touch panel 121. Therefore, the protection plate 130 protects the display device 100 from friction, shock, dust, and chemical pollution from the front surface side of the display device 100 and also provides aesthetic design.

According to the display device 100 of the present embodiment, the bent flexible circuit board 122 is hidden on the back surface side of the touch panel 121 seen from the front surface side of the protection plate 130. This further reduces the frame area of the display device 100.

According to the display device 100 of the present embodiment, the display panel 110 includes the liquid crystal panel 112. Therefore, compared to the display device including a cathode-ray tube, the display device becomes thinner and lighter and displays images with high resolution.

According to the display device 100 of the present embodiment, the display panel 110 includes the backlight 111. Therefore, images of high brightness and high contrast can be displayed regardless of the surrounding light level. The liquid crystal panel 112 may be a reflective type liquid crystal panel that includes a reflection layer on a back surface side or an inside thereof. In such a configuration, the liquid crystal panel 112 may include a front light on the front surface side thereof instead of the backlight 111. With such a configuration, images of high brightness and high contrast can be displayed regardless of the surrounding light level.

### Second Embodiment

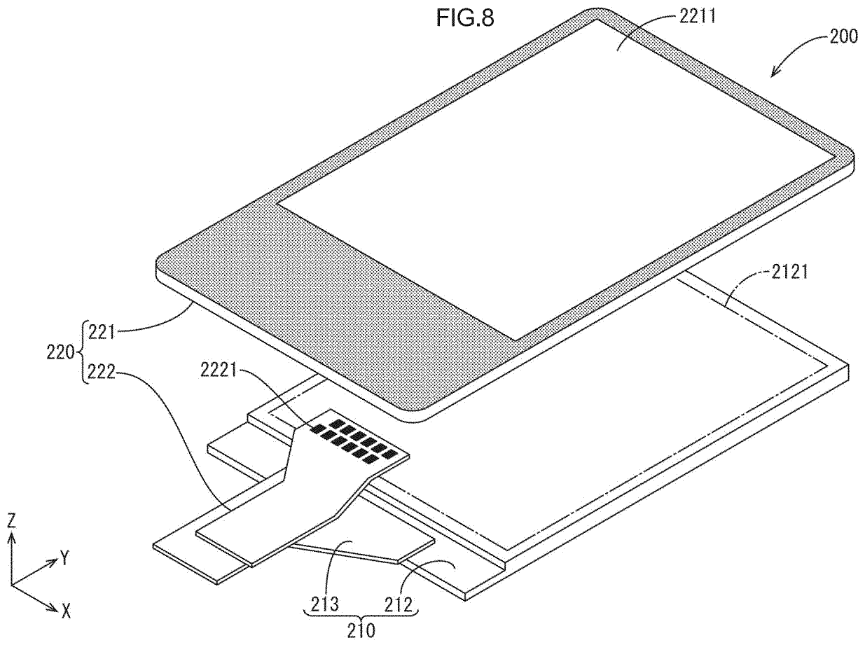

FIG. 8 is an exploded perspective view of a display device 200 according to a second embodiment. Components same as those of the first embodiment are provided with the same symbols and the components and configurations same as those of the first embodiment will not be described. A display device according to the present embodiment includes a display panel 210 and a touchscreen panel including a protection plate 220.

<Display Panel 210>

The display panel 210 has a plate shape and includes a display region 2121 on a front surface thereof. The display panel 210 displays a certain image on the display region 2121 in response to input of an electric signal. The display panel 210 includes an organic EL panel (an organic electroluminescence panel) 212 and a flexible circuit board 213.

<Organic EL Panel 212>

The organic EL panel 212 has a quadrangular shape and includes a light emitting layer. The light emitting layer includes light emitting diodes (LED) that are an organic compound and is enclosed in the display region 2121. The display device generally includes the light emitting diodes that are enclosed in a matrix to display various images; however, the display device may be other type of display device. The light emitting diode includes an anode and a cathode and a voltage is applied between the anode and the cathode such that electrons and electron holes are injected therefrom. The injected electrons and electron holes pass through an electron transfer layer and an electron hole transfer layer, respectively, and combined together in the light emitting layer. Light emitting material in the light emitting layer is excited by energy created by the combination. Light is output when the excited state turns back to a ground state again. A metal thin film of aluminum, a silver/magnesium alloy, and calcium is generally used for the cathode, and a transparent metal thin film called indium tin oxide is generally used for the anode. However, other material may be used. A color filter or a color conversion layer may be included to display various colors. A backlight and a front light may not be necessary because the organic EL panel 212 emits light.

<Flexible Circuit Board 213>

The organic EL panel 212 has no organic LEDs on a section thereof near a −Y direction side and one end of the flexible circuit board 213 is connected to the section of the organic EL panel 212. Electric signals for emitting the organic LEDs of the organic EL panel 212 are transmitted to the organic EL panel 212 through the flexible circuit board 213. The flexible circuit board 213 includes a flexible substrate and conductive members printed on the flexible substrate. The organic EL panel 212 makes the organic LEDs to emit light based on the electric signals supplied to the conductive members of the flexible circuit board 213.

<Touchscreen Panel Including Protection Plate 220>

The touchscreen panel including a protection plate 220 includes a touch panel including a protection plate 221 and a flexible circuit board 222.

<Touch Panel Including Protection Plate 221>

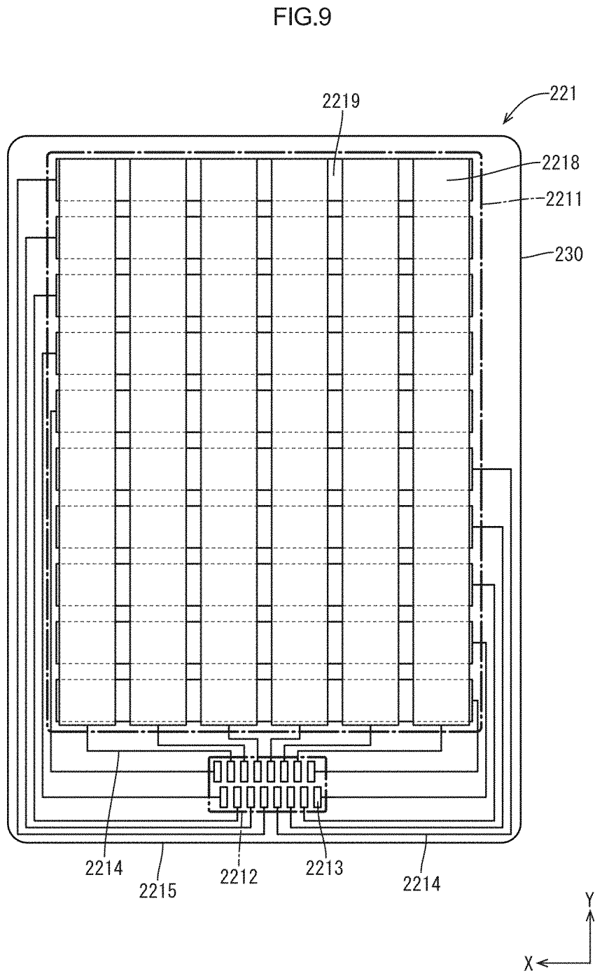

FIG. 9 is aback side view of the touch panel including a protection plate 221. The touch panel including a protection plate 221 includes a protection plate 230 as a base and a touch panel formed on a back surface of the protection plate 230.

<Protection Plate 230>

The protection plate 230 is made of glass or resin. The protection plate 230 has a region that overlaps (overlaps in the Z direction) the display region 2121 of the organic EL panel 212 and the region is preferably transparent and other sections may be colored. The protection plate 230 has a quadrangular shape whose corners are chamfered to be a round shape in a back side view. However, the protection plate 230 may have other shape. The protection plate 230 protects the display device 200 from friction, shock, dust, and chemical pollution from the front surface side o the display device 200 and also provides aesthetic design.

A touch panel including X electrodes 2218, Y electrodes 2219, connection terminals 2213, and panel lines 2214 is formed on a back surface of the protection plate 230. The X electrodes 2218 and the Y electrodes 2219 are disposed in the detection region 2211 and the connection terminals 2213 are disposed in the terminal region 2212.

The touch panel including a protection plate 221 includes conductive layers including the X electrodes 2218, the Y electrodes 2219, the connection terminals 2213, and the panel lines 2214 and an insulation layer that are stacked on each other. An insulation layer is between the X electrodes 2218 and the Y electrodes 2219 so that the X electrodes 2218 and the Y electrodes 2219 are not electrically connected. The connection terminals 2213 are through a layer on which the panel lines 2214 are formed and a layer on the most outer back side layer (for example, a protection layer) of the touch panel including a protection plate 221 and is exposed from the back surface of the touch panel including a protection plate 221. The panel lines 2214 may be formed on any one of the layers included in the touch panel including a protection plate 221.

<Connection Terminal 2213>

A row of three or more connection terminals 2213 are arranged linearly in the X direction and two rows of the connection terminals 2213 are arranged in a direction (the Y direction) perpendicular to the arrangement direction. The connection terminals 2213 included in the two rows may be arranged in a staggered form or in a zigzag form as illustrated in FIG. 9 or the connection terminals 2213 included in the two rows may be arranged in a matrix so as to be aligned in the Y direction.

<Panel Lines 2214>

The panel lines 2214 are electrically connected to the X electrodes 2218 or the Y electrodes 2219 and the connection terminals 2213. Among the two rows of the connection terminals 2213, one row that is closer to the detection region 2211, that is, the connection terminals 2213 on the +Y direction side are connected to the X electrodes 2218 except for the two connection terminals 2213 on the two ends. Other connection terminals 2213 are connected to the Y electrodes 2219. Total of four connection terminals 2213 on the two ends of each row are connected to the panel lines 2214 in the direction (the +X direction or the −X direction) in which the three or more connection terminals are linearly arranged. Except for the two connection terminals 2213 on the two ends, the connection terminals 2213 included in one of the two rows that is farther away from the detection region 2211, that is, the connection terminals 2213 on the −Y direction side are connected to the panel lines 2214, which are the detour lines, from a side where the detection region 2211 is not present seen from the connection terminals 2213.

The detour lines include a detour section extending on the side where the detection region 2211 is not present seen from the connection terminals 2213 and along outer periphery of the touch panel including a protection plate 221. Furthermore, the connection terminals 2213 that are connected to the detour lines are arranged on an inner side from the detour section in the touch panel including a protection plate 221.

<Flexible Circuit Board 222>

The connection terminals 2213 are arranged in the two rows in the present embodiment. FPC terminals of the flexible circuit board 222 are also arranged in two rows similar to the connection terminals 2213.

<Assembling of Display Device 200>

Assembling of the display device 200 will be described. One end of the flexible circuit board 213 is connected to the organic EL panel 212 to configure the display device 200. One end of the flexible circuit board 222 is electrically connected to the touch panel including a protection plate 221 to configure the touchscreen panel including a protection plate 220. Next, the organic EL panel 212 is disposed on the back surface side of the detection region 2211 of the touchscreen panel including a protection plate 220 such that the display region 2121 of the organic EL panel 212 is superimposed on the back surface of the detection region 2211.

Next, the flexible circuit boards 213, 222 are bent. Specific processes are same as those of the first embodiment.

### Advantageous Effects of the Present Embodiment

According to the display device 200 of the present embodiment, the display panel 210 is an organic EL panel. Therefore, compared to the display device including a cathode-ray tube, the display device becomes thinner and lighter and displays images with high resolution.

According to the display device 200 of the present embodiment, the touch panel is formed on the back surface of the protection plate 230, which is used as a base member. This reduces the number of components and contributes to reduction in a thickness, a weight, and a product cost.

According to the display device 200 of the present embodiment, the connection terminals 2213 and the FPC terminals 2221 are arranged in two rows, respectively. Accordingly, a length of the terminal region 2212 extending in the direction in which three or more connection terminals 2213 are linearly arranged is reduced. This reduces a width of the flexible circuit board 222. Furthermore, a greater amount of connection terminals 2213 can be arranged in the frame area of the touch panel including a protection plate 221. The number of rows of the connection terminals 2213 and the FPC terminals 2221 may be three or more.

According to the display device 200 of the present embodiment, among the three or more connection terminals 2213 linearly arranged, the connection terminals on the two ends are connected to the panel lines 2214 from the direction (the X direction) in which the three or more connection terminals are linearly arranged. According to such a configuration, the number of connection terminals 2213 that are connected to the panel lines from the +Y direction and/or the −Y direction that are perpendicular to the X direction is reduced. This reduces an area between the detection region 2211 and the terminal region 2212 and the number of the panel lines 2214 that are necessarily routed between an area between the terminal region 2212 and the edge 2215. Accordingly, the frame area of the display device 200 is further reduced.

1. A touchscreen panel comprising:
a touch panel having a plate shape having a front surface and a back surface; and
a flexible circuit board one end of which is electrically connected to the touch panel, wherein
the touch panel includes
a detection region where contact of an operator from a front surface side can be detected, and
a terminal region where connection terminals to be connected to the flexible circuit board are disposed on a back surface side,
the detection region and the connection terminals are connected to each other via panel lines formed on the touch panel, and
one of the panel lines is a detour line that is connected to one of the connection terminals from aside where the detection region is not present seen from the connection terminals.

2. The touchscreen panel according to claim 1, wherein the detour line has a detour section that extends on the side where the detection region is not present seen from the connection terminals and along an outer periphery of the touch panel.

3. The touchscreen panel according to claim 2, wherein the connection terminal connected to the detour line is disposed on an inner side than the detour section within a plane surface of the touch panel.

4. The touchscreen panel according to claim 1, wherein the connection terminals include three or more connection terminals and the three or more connection terminals are linearly arranged.

5. The touchscreen panel according to claim 4, wherein the detection region has a linear outer peripheral edge section, and a direction in which the three or more connection terminals are linearly arranged is parallel to an extending direction in which the linear outer peripheral edge section extends.

6. The touchscreen panel according to claim 4, wherein the touch panel has a shape having a linear side that is farthest from the connection terminals in a plan view, and a direction in which the three or more connection terminals are linearly arranged is parallel to an extending direction in which the linear side extends.

7. The touchscreen panel according to claim 1, wherein the touchscreen panel is an electrostatic capacitance type.

8. The touchscreen panel according to claim 1, wherein the flexible circuit board is connected to one of a transistor element, a resistance element, and a condenser element, a chip enclosing the one element with resin, or a circuit board having the chip thereon.

9. The touchscreen panel according to claim 1, further comprising a protection plate on the front surface of the touch panel.

10. A display device comprising the touchscreen panel according to claim 4, wherein
the detection region includes a transparent part,
a display panel is disposed on a back surface side of the detection region, and
a display region of the display panel is superimposed on a back surface of the detection region.

11. The display device according to claim 10, wherein the flexible circuit board is bent toward a back surface side of the display panel and apart of the flexible circuit board is disposed on the back surface side of the display panel.

12. The display device according to claim 11, wherein the flexible circuit board is bent in a direction that is perpendicular to a direction in which the three or more connection terminals are linearly arranged.

13. The display device according to claim 11, wherein the flexible circuit board that is bent is hidden on a back surface side of the touch panel seen from a front surface side of the touch panel.

14. The display device according to claim 11, wherein the flexible circuit board is connected to one of a transistor element, a resistance element, and a condenser element, a chip enclosing the one element with resin, or a circuit board having the chip thereon, and the one element is disposed on the back surface side of the display panel.

15. The display device according to claim 10, further comprising a protection plate on the front surface side of the touch panel.

16. The display device according to claim 15, wherein the flexible circuit board that is bent is hidden on a back surface side of the protection plate seen from a front surface side of the protection plate.

17. The display device according to claim 10, wherein the display panel includes a liquid crystal panel.

18. The display device according to claim 17, wherein the display panel includes a backlight or a front light.

19. The display device according to claim 10, wherein the display panel is an organic EL panel.

20. The display device according to claim 15, wherein the touch panel is formed on a back surface of the protection plate that is used as a base member.
